(19) United States
(12) Patent Application Publication
(10) Pub. No.: US 2012/0312373 A1
(43) Pub. Date: Dec. 13, 2012

(54) Solar Roof Panel Assembly and Method for Installation

(75) Inventors: Willard C. Hudson, JR., Southlake, TX (US); James F. Sauter, Cleburne, TX (US); Kevin B. Pelka, Lake Elsinore, CA (US); Geoffrey S. Allan, Auckland (NZ); Peter B. Richards, Auckland (NZ); David R. Painter, North Shore Auckland (NZ)

(73) Assignee: DECRA ROOFING SYSTEMS, INC., Grand Prairie, TX (US)

(21) Appl. No.: 13/492,475

(22) Filed: Jun. 8, 2012

Related U.S. Application Data
(60) Provisional application No. 61/495,517, filed on Jun. 10, 2011.
(60) Provisional application No. 61/497,625, filed on Jun. 16, 2011.

(51) Int. Cl. H01L 31/0203; H01L 31/18

(52) U.S. Cl. 136/259; 29/890.033

(57) ABSTRACT

A solar roof panel assembly for new construction or retrofit installation above a roof deck of a building structure comprises a metal roof panel base, at least one solar cell, a stone coating, and an electrical junction box fastened to the back of the metal roof panel base. The electrical junction box houses electrical components connected to the solar cell, and electrical connection elements extend from the electrical junction box. The solar roof panel assembly may be installed such that an air gap is created between the solar roof panel assembly and the roof deck, and cabling and other electrical components may be placed in the air gap. Multiple solar roof panel assemblies may be interconnected. A solar roof panel assembly may replace a previously-installed roof panel, and may be aesthetically and/or structurally similar to adjacent previously-installed roof panels.

### CROSS-REFERENCE TO RELATED APPLICATIONS

This application claims the benefit of U.S. Provisional Application No. 61/495,517, filed on Jun. 10, 2011, and U.S. Provisional Application No. 61/497,625, filed on Jun. 16, 2011, which applications are hereby incorporated herein by reference.

### TECHNICAL FIELD

This disclosure generally relates to solar roofing systems for converting light energy into electricity, and more particularly relates to solar roof panel assemblies and methods for installing solar roof panel assemblies on building structures.

### BACKGROUND

Photovoltaic, or solar, roof panels typically consist of grids of raised black cells that generally come in the form of large rectangular panels. These panels are typically placed into rack systems that are mounted onto a roof. In addition to being aesthetically unappealing, building owners may be reluctant to embrace the technology because installing solar panel rack systems often require puncturing an existing roof to bolt on mounting supports, which may compromise the integrity of the roof, may necessitate the use of additional flashing material, and may void the roof's warranty.

Building-integrated photovoltaics, or BIPVs, are photovoltaic materials that may be used in place of conventional building materials rather than in addition to conventional building materials. But when BIPV roof panels such as asphalt solar shingles are applied directly to the roof deck, the solar cells may overheat and lose energy efficiency, or in some cases stop working completely. BIPV roof panels may also be difficult to retrofit on an existing roof if the BIPV roof panels are insufficiently similar in size and installation requirements to the existing roof panels. Furthermore, retrofitting BIPV roof panels on an existing roof may be aesthetically unappealing if the BIPV roof panels are insufficiently similar in appearance to the existing roof panels.

### SUMMARY

Disclosed herein are various embodiments of a solar roof panel assembly for installation above a roof deck of a building structure. The solar roof panel assembly may be used for converting light energy into electricity. The solar roof panel assembly may comprise a metal roof panel base. The metal roof panel base may comprise a front surface and a back surface. The front surface may have a reserved area and a non-reserved area. The reserved area may be recessed. A stone coating may cover all or a portion of the non-reserved area. In some embodiments, the stone coating may comprise ceramic-coated stone granules.

At least one solar cell may be fastened to the metal roof panel base within the reserved area. An electrical junction box may be positioned on the back surface, and may house electrical components connected to the solar cells. The electrical components may extend from the solar cells through an aperture in the metal roof panel base. Electrical connection elements adapted for connecting to the building structure electrical system and for interconnecting multiple solar roof panel assemblies may extend from the electrical junction box. In some embodiments, electrical connection elements comprise multi-contact connectors.

In some embodiments, the solar roof panel assembly may further comprise a radiant barrier fastened to the back surface. The radiant barrier may comprise a reflective material, and may be fastened with an adhesive. The radiant barrier may cover the entire back surface of the metal roof panel base. Solar cells may be fastened to the metal roof panel base with an adhesive, such as tape or glue.

Also disclosed herein are various embodiments of a method for installing a solar roof panel assembly above a roof deck of a building structure. Both new construction and retrofit installations are disclosed. A method may comprise identifying a target site above the roof deck and fastening a solar roof panel assembly to the roof deck at the target site such that an air gap is created between the solar roof panel assembly and the roof deck. The method may further comprise electrically connecting the solar roof panel assembly to the building structure electrical system, and may also comprise electrically interconnecting multiple solar roof panel assemblies. In some embodiments the solar roof panel assembly may be fastened to battens, which may be fastened to counter battens, which may be fastened to the roof deck.

In some embodiments, a previously-installed roof panel may have formerly occupied the target site, and the method may comprise removing the previously-installed roof panel. In some embodiments, the previously-installed roof panel may be a DECRA® Roofing Systems roof panel. Previously-installed roof panels adjacent to the target site may have form and/or functional configurations similar to the solar roof panel assembly.

### BRIEF DESCRIPTION OF THE DRAWINGS

FIG. 1A illustrates an example solar roof panel assembly in accordance with the present disclosure;

FIG. 1B illustrates an exploded view of an example solar roof panel assembly in accordance with the present disclosure;

FIGS. 2A and 2B illustrate an example solar roof panel assembly and an associated example metal roof panel base in accordance with the present disclosure;

FIGS. 3A and 3B illustrate an example solar roof panel assembly and an associated example metal roof panel base in accordance with the present disclosure;

FIGS. 4A and 4B illustrate an example solar roof panel assembly and an associated example metal roof panel base in accordance with the present disclosure;

FIG. 5 is a flow diagram illustrating an embodiment of a fabrication process for a solar roof panel assembly, in accordance with the present disclosure;

FIG. 6 illustrates an example new construction installation of a solar roof panel assembly, in accordance with the present disclosure;

FIG. 7 is a flow diagram illustrating an embodiment of a new construction installation process for a solar roof panel assembly, in accordance with the present disclosure; and

FIG. 8 illustrates an example new retrofit installation of a solar roof panel assembly, in accordance with the present disclosure.

### DETAILED DESCRIPTION

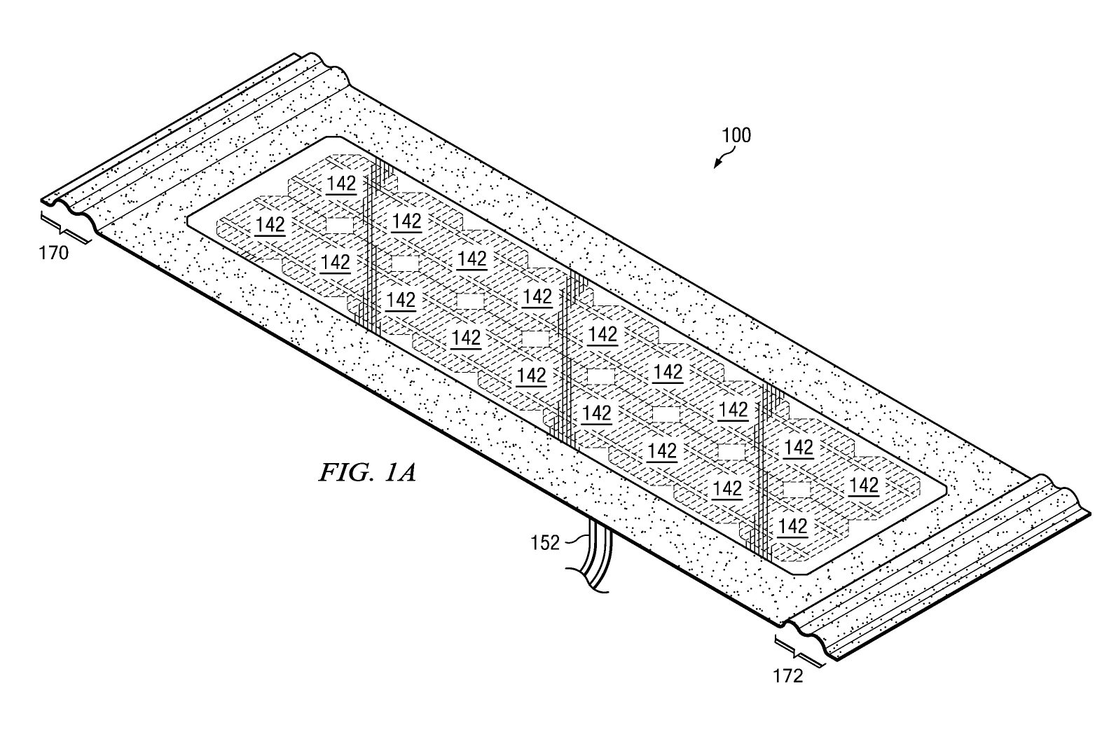

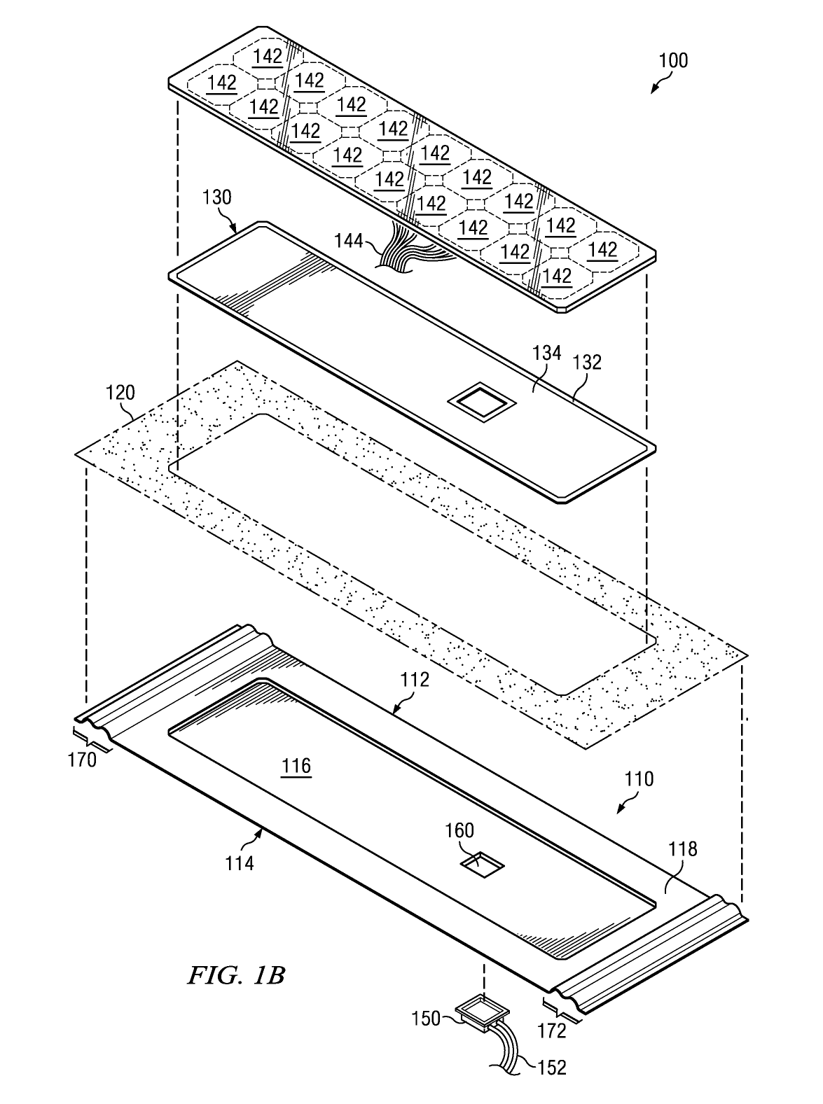

An example solar roof panel assembly 100 is illustrated in FIG. 1A. Solar roof panel assembly 100 may be described as a building-integrated photovoltaic (BIPV). BIPVs are photovoltaic materials that may be used to replace conventional building materials. One or more solar roof panel assemblies 100 may be installed above a roof deck of a building structure. Besides performing the functions of a conventional roof panel, such as shielding the building and its contents from rain, snow, wind, heat, cold, and other weather effects, solar roof panel assembly 100 may be used for converting light energy from the sun into electricity. Solar roof panel assemblies 100 may be incorporated into the construction of new buildings and may also be retrofitted into existing buildings. Solar roof panel assemblies 100 may be connected to the electrical system of the building to provide electricity for the building. Excess electricity generated by solar roof panel assemblies 100 may be directed to a utility grid connected to the building or may be stored, for example, in batteries, for use during the night and/or during periods of low sunlight.

An exploded view of example solar roof panel assembly 100 is illustrated in FIG. 1B. Metal roof panel base 110 has a front surface 112 and a back surface 114. In some embodiments, metal roof panel base 110 is substantially rectangular in shape, and measures approximately 12 to 15 inches by approximately 50 to 51 inches, although other shapes and sizes are contemplated. Metal roof panel base 110 may be made of steel, and may be rigid enough to tolerate reasonable loads with minimal risk of cracking or significant elastic recovery. In some embodiments, metal roof panel base 110 may be made of structural grade steel with a minimum tensile strength of 37 ksi, although other metals suitable for a roofing product are contemplated. Metal roof panel base 110 may also be coated on some or all surfaces for corrosion protection. In some embodiments, metal roof panel base 110 is made of flexible, 26-gauge steel with an aluminum-zinc alloy coating.

Metal roof panel base 110 may include a reserved area 116 and a non-reserved area 118. In some embodiments, reserved area 116 may be centrally located on metal roof panel base 110, and non-reserved area 118 may extend three to four inches around reserved area 116, although other reserved area/non-reserved area configurations are contemplated. In some embodiments, part or all of reserved area 116 is recessed, and part or all of non-reserved area 118 is not recessed. In some embodiments, reserved area 116 is not recessed, and may be flush or even elevated compared to non-reserved area 118.

Metal roof panel base 110 may also include at least one overlap portion 170 and at least one complementary underlap portion 172. Overlap portion 170 of a first solar roof panel assembly may be placed over underlap portion 172 of an adjacent solar roof panel assembly for a complementary fit. Metal roof panel base 110 may include multiple overlap and underlap portions. In some embodiments, metal roof panel base 110 may have an overlap portion on one side and an underlap portion on the opposing side, enabling a complementary fit, for example, when panels are placed left-to-right or right-to-left. In some embodiments, metal roof panel base 110 may have an overlap portion on top and an underlap portion on bottom, enabling a complementary fit, for example, when panels are placed top-to-bottom or bottom-to-top.

In some embodiments, a radiant barrier (not shown) may be fastened to back surface 114 of metal roof panel base 110. Such a radiant barrier may comprise a reflective material and may be fastened to metal roof panel base 110 with an adhesive, with mechanical fasteners, may be sprayed on, or may be fastened in another appropriate manner. The radiant barrier may cover all or part of back surface 114. In some embodiments, a reflective backing covers the entire back surface 114 of metal roof panel base 110.

Stone coating 120 covers some or all of non-reserved area 118. Stone coating 120 may provide additional protection for metal roof panel base 110 in addition to providing an attractive appearance. In some embodiments, a primer (not shown) and/or a basecoat (not shown) may by applied to all or part of metal roof panel base 110 prior to application of stone coating 120. A primer, such as an acrylic primer, may be applied to enhance adhesion of stone coating 120 to metal roof panel base 110. A basecoat, such as an acrylic resin binder, may further enhance adhesion of stone coating 120 to metal roof panel base 110, and may also protect the underlying material from water and UV light. Stone coating 120 may include stone granules sized and applied to ensure maximum coverage of non-reserved area 118, and such stone granules may be colored to enhance appearance. In some embodiments, stone coating 120 may comprise ceramic-coated stone granules. An overglaze (not shown), such as an acrylic overglaze, may be applied to all or part of stone coating 120 to give the granules a semi-gloss appearance and to enhance resistance to physical damage.

One or more solar cells 142 may be fastened to reserved area 116 of metal roof panel base 110. Solar cells 142, also referred to as photovoltaic cells or photoelectric cells, may be of any design appropriate for converting the energy of light, especially sunlight, into electricity. Multiple solar cells 142 may be electrically connected, either in series, in parallel, or in both series and in parallel, and may be encapsulated into a solar module. In some embodiments, a single solar module comprising one or more solar cells 142 is fastened to all or part of reserved area 116 of metal roof panel base 110. Solar cells 142 may be covered with a sheet of glass or other transparent or translucent material that allows light to pass through while protecting solar cells 142 from damage due to rain, hail, wind-driven debris, or other hazards.

Solar cells 142 (or a solar module comprising solar cells 142) may be fastened to metal roof panel base 110 with adhesive layer 130. Any appropriate adhesive may be used, such as adhesive tape 132 or glue 134. In some embodiments, adhesive tape 132 forms a closed loop inside the perimeter of reserved area 116, and may also form a closed loop around aperture 160. Glue 134 may then fill the area surrounded by adhesive tape 132. In some embodiments, only glue 134 may be used, in other embodiments, only adhesive tape 132 may be used, and in still other embodiments, a different adhesive or combination of adhesives may be used. In some embodiments, adhesive tape 132 may be butyl foam tape. In some embodiments, glue 134 may be a polyurethane- or a silicon-based glue designed for photovoltaic applications.

Electrical components 144 associated with delivering electricity from solar cells 142 may pass through aperture 160 in metal roof panel base 110 and may be housed in electrical junction box 150. Electrical junction box 150 may be positioned on the back surface 114 of metal roof panel base 110, and at least one electrical connection element 152 may extend from electrical junction box 150. In some embodiments, electrical junction box 150 is centrally positioned on back surface 114. In other embodiments, electrical junction box 150 may be positioned toward the top, bottom, or to either side of metal roof panel base 110. Electrical connection elements 152 may be connected to the electrical system of the building structure and may deliver electricity to the building and/or to a utility grid connected to the building.

Electrical connection elements 152 may be connected to the electrical connection elements of other solar roof panel assemblies 100, either in series, in parallel, or in both series and in parallel, to create a solar panel array with a desired peak DC voltage and current. In some embodiments, a first electrical connection element may be adapted for connecting to one solar roof panel assembly, and a second electrical connection element may be adapted for connecting to another solar roof panel assembly. In some embodiments, the first element may be a positive multi-contact connector, and the second element may be a negative multi-contact connector.

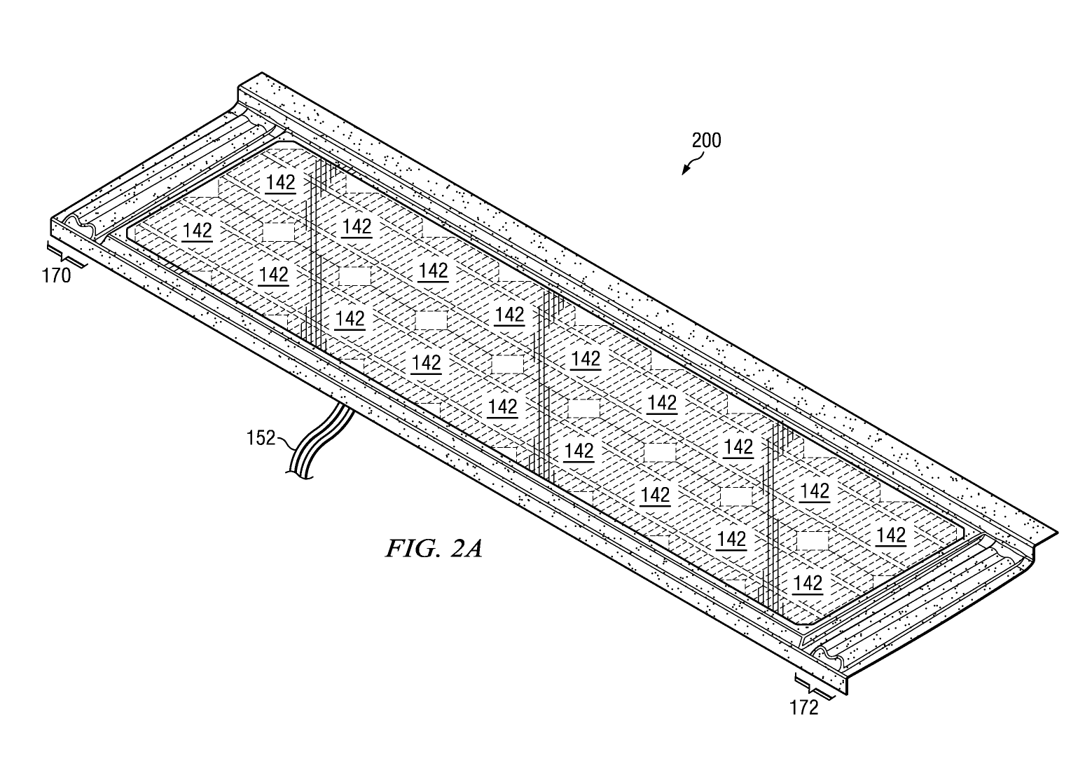

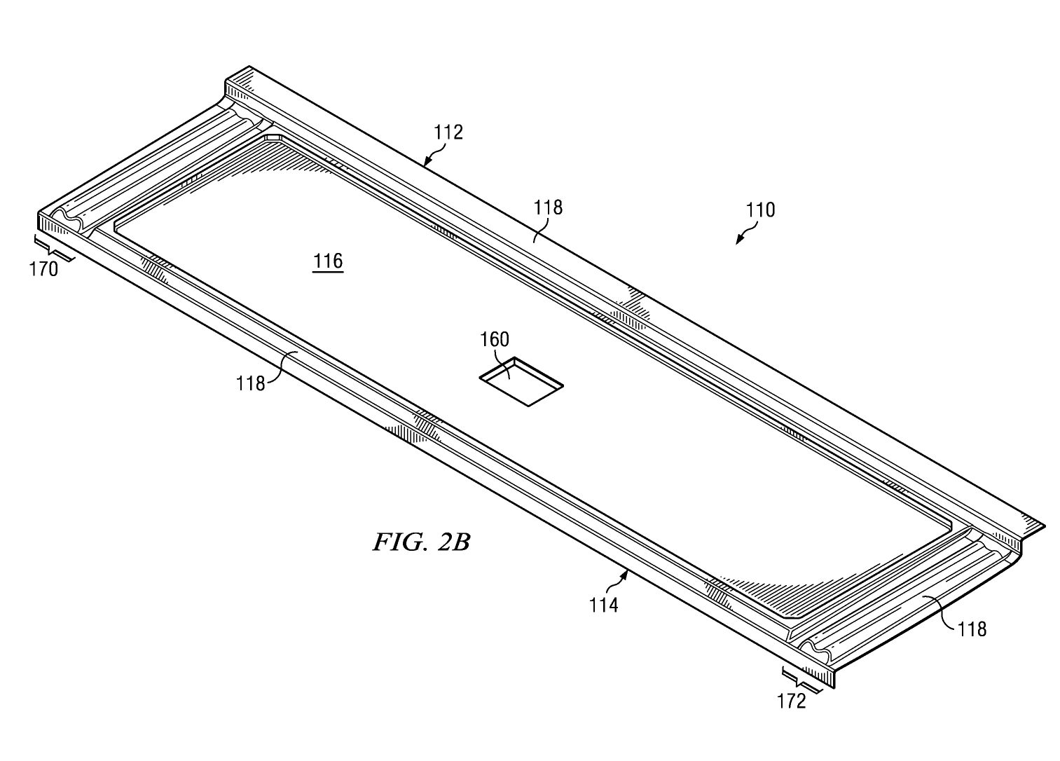

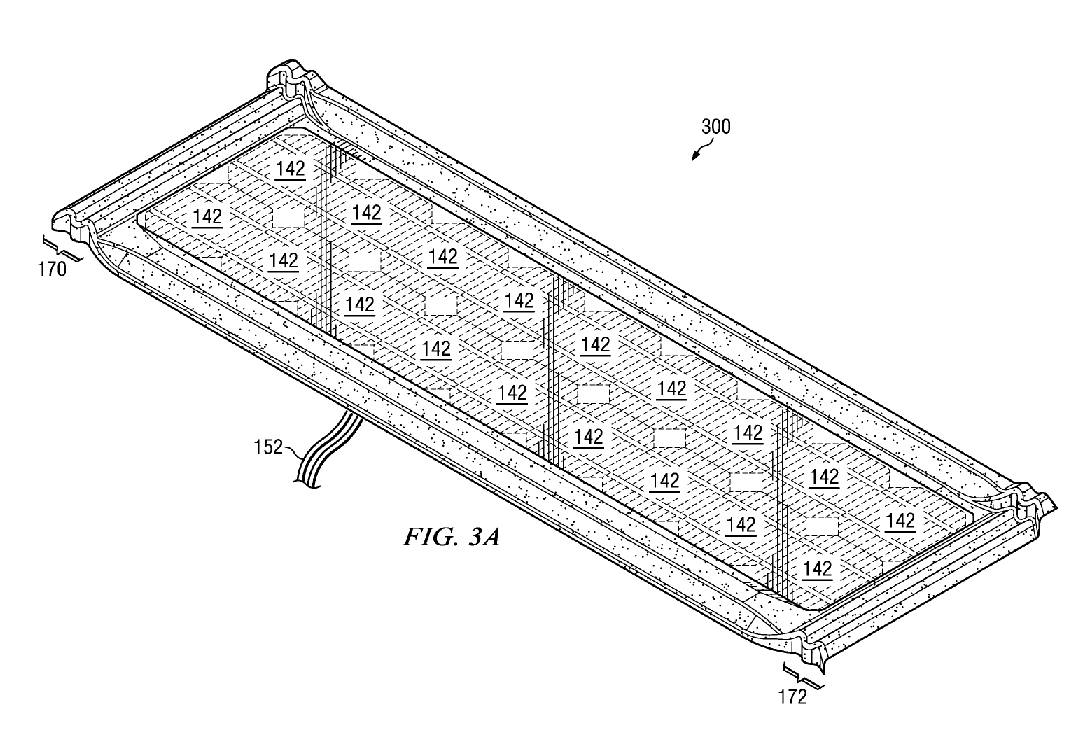

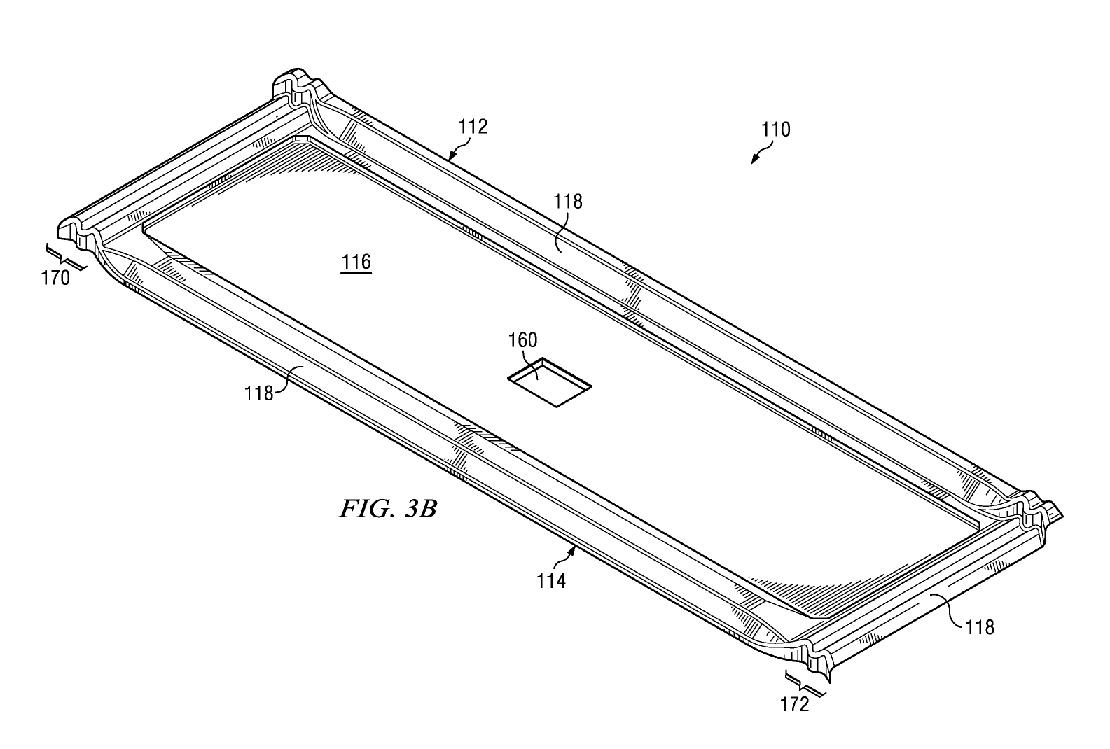

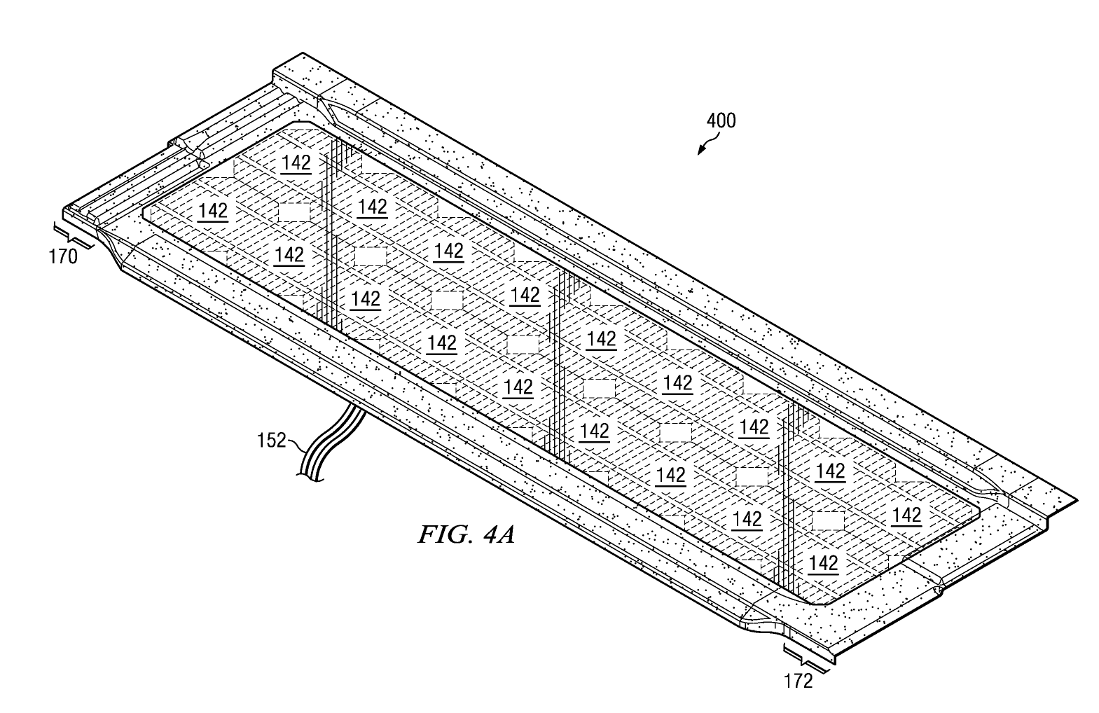

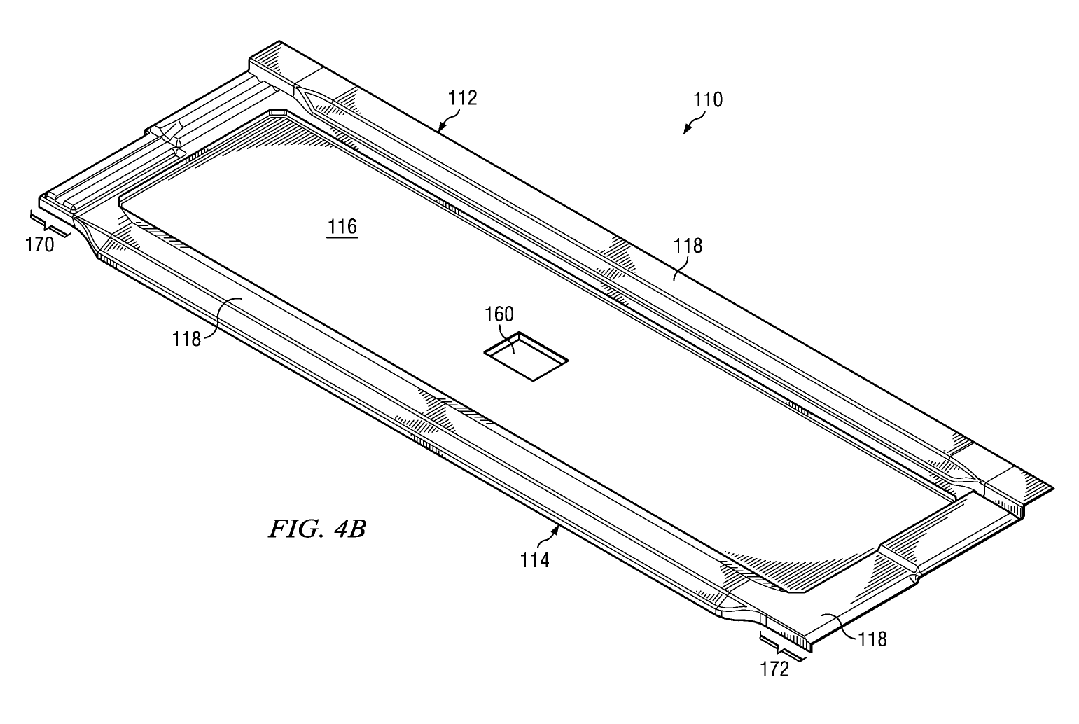

An example embodiment 200 of solar roof panel assembly 100 is illustrated in FIGS. 2A and 2B. An example embodiment 300 of solar roof panel assembly 100 is illustrated in FIGS. 3A and 3B. An example embodiment 400 of solar roof panel assembly 100 is illustrated in FIGS. 4A and 4B. Like reference numerals in these example embodiment illustrations refer to like elements as discussed above in FIGS. 1A and 1B.

### Fabrication

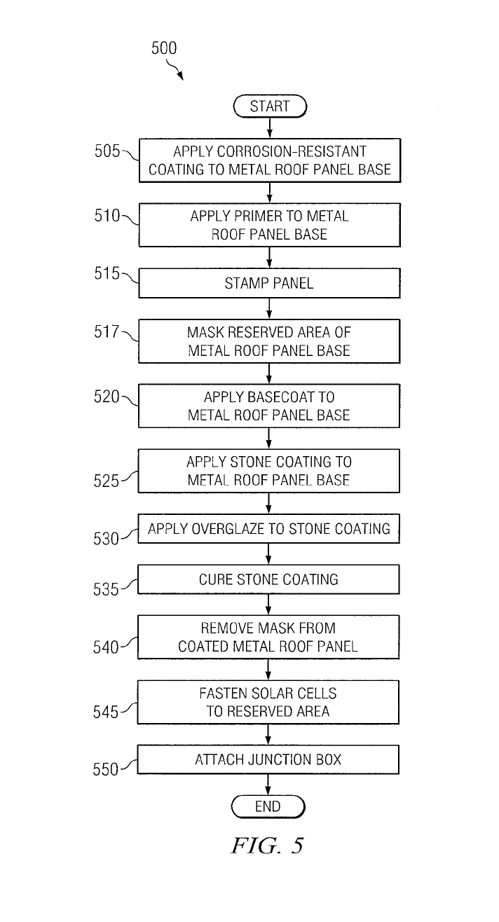

FIG. 5 is a flowchart illustrating an example method 500 for fabricating an embodiment of solar roof panel assembly 100. It should be borne in mind that the order of the actions described in this detailed description should in no way be considering limiting of the invention. The claims set forth in any patent that issues herefrom will determine the scope of protection, and the order (and whether to include) some or all of these actions may be varied according to manufacturing and design needs.

The exemplary process described in this embodiment begins with a base panel made of metal, for example, structural grade steel with a minimum tensile strength of 37 ksi. The base panel may be rigid enough to tolerate reasonable loads, while allowing profile designs without the risk of cracking or significant elastic recovery. At step 505, corrosion protection for the base panel is achieved, for example, by passing through a bath of molten aluminum-zinc alloy. This coating combines the protection and strength of both aluminum and zinc. A significant benefit of the zinc component is its ability to protect exposed areas such as cut edges, drilled holes, and scratches. In some embodiments, a different corrosion-resistant coating may be applied to part or all of the base panel. In some embodiments, no corrosion-resistant coating may be applied to the base panel.

In some embodiments at step 510, a primer may be applied to the base panel. The primer may be an acrylic coating primer that is applied to both sides of the panel after application of the aluminum-zinc coating or other corrosion-resistant coating to provide a uniform substrate that enhances adhesion of subsequent coatings. After the described primer application 510, the base panel may stamped through a metal stamping process 515 to give the panel its physical form.

In the presently described embodiment, after stamping 515, a reserved area of the base panel may be masked 517 to prevent further coating of the reserved area. In some embodiments where corrosion protection is applied, the reserved area may be masked prior to the application of corrosion protection. In some embodiments, a different primer may be applied to part or all of the non-masked area of the metal roof panel base. In some embodiments, no primer may be applied to the non-masked area of the metal roof panel base.

A basecoat may be applied 520 to the non-masked area of the metal roof panel base. In some embodiments, the basecoat is formed by applying an acrylic resin binder that serves as an adhesive that will bond a stone coating to the base metal and also protects the underlying material from water and ultraviolet light. In some embodiments, a different basecoat may be applied to part or all of the non-masked area of the metal roof panel base. In some embodiments, no basecoat may be applied to the non-masked area of the metal roof panel base.

A stone coating may be applied 525 to the non-masked area of the metal roof panel base. In some embodiments, the stone coating comprises ceramic-coated stone granules that are sized and applied in such a way to ensure maximum coverage of the basecoat, although other stone coating formulations are contemplated. The stone coating provides further protection from water and ultraviolet light in addition to providing an attractive appearance in an array of colors. An overglaze may further be applied 530 to the non-masked area of the metal roof panel base. In some embodiments, an acrylic overglaze is applied as a final coating that gives the stone granules a semi-gloss appearance. This tough, thin acrylic finish bonds to the granules and encapsulates them with a coating that enhances the panel's resistance to physical damage. In some embodiments, a different overglaze may be applied to part or all of the non-masked area of the metal roof panel base. In some embodiments, no overglaze may be applied to the non-masked area of the metal roof panel base.

The stone coating and overglaze processes may be followed by curing 535, such as heat curing. In some embodiments, the stone coating is cured at approximately two hundred degrees Fahrenheit. In some embodiments, heat curing or other curing of the stone coating may not be performed.

In some embodiments, zinc-aluminum and other coatings are applied to the base metal while in a coiled rolled form. The metal roof panel base may then be cut and stamped to the shingle profile and masked. In some embodiments, only the stone coating is applied after masking.

After the stone coating and any other coatings are applied to all or part of the non-masked area of the metal roof panel base, the mask is removed 540 and one or more solar cells are fastened 545 onto the area previously masked. Multiple solar cells may be electrically connected, either in series, in parallel, or in both series and in parallel, and may be encapsulated into a solar module. In some embodiments, a single solar module comprising one or more solar cells is fastened onto the area previously masked. It should further be noted that metal roof panels may be used that do not include a stone coating. In such embodiments, the panels may be painted before or after the stamping process 515.

The fastening process may include the application of an adhesive material to the previously masked area. The adhesive material may be adhesive tape, glue, or any other adhesive suitable for fastening the solar cells to the metal roof panel base. The adhesive should cover the previously masked area completely to form a watertight seal, but seepage of adhesive outside of the previously masked area should be minimized. In some embodiments, an adhesive tape such as thin butyl foam tape is used to cover the previously masked area. In some embodiments, glue such as Dow Corning® solar adhesive is used to cover the previously masked area. A combination of adhesive tape and glue may also be used. In some embodiments, adhesive tape is applied just inside the perimeter of the previously masked area, and may also encircle an aperture in the previously masked area. Glue may then be applied in the area bounded by adhesive tape.

After the adhesive is applied, the solar cells are pressed into the previously masked area. The solar cells may be covered with a sheet of glass or other transparent or translucent material that allows light to pass through while protecting the solar cells from damage due to rain, hail, wind-driven debris, or other hazards. In some embodiments, the solar cells and covering form a prefabricated unit that is pressed into the previously masked area.

Electrical components associated with delivering electricity from the solar cells may be passed through an aperture in the metal roof panel base. These electrical components may be housed in a junction box attached 550 to the back surface of the solar roof panel assembly. In some embodiments, the electrical junction box is centrally positioned on the back surface of the solar roof panel assembly. In other embodiments, the electrical junction box may be positioned toward the top, bottom, or to either side of the metal roof panel base. Electrical connection elements, such as positive and negative multi-contact connectors, may extend from the electrical junction box.

Although method 500 recites specific steps for fabricating an embodiment of solar roof panel assembly 100, such an embodiment may be fabricated using additional steps, fewer steps, different steps, or a combination of these and other steps. In addition, different embodiments of solar roof panel assembly 100 may be fabricated using additional steps, fewer steps, different steps, or a combination of these and other steps.

### New Construction Installation

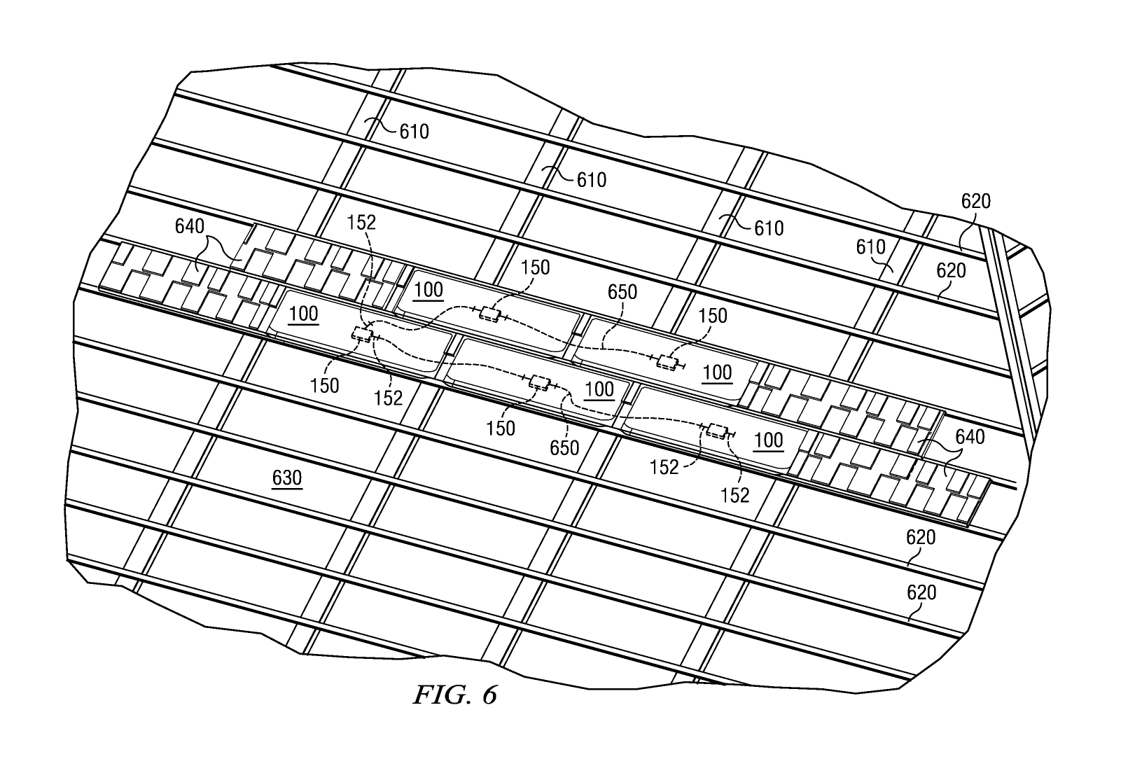

FIG. 6 illustrates an example new construction installation of solar roof panel assemblies 100. Solar roof panel assemblies 100 should be installed above roof deck 630 such that an air gap is created between solar roof panel assemblies 100 and roof deck 630. This air gap provides space for electrical junction boxes 150 and electrical connection elements 152, as well as any additional electrical cabling 650 or other materials that may be required for installation of solar roof panel assemblies 100, for electrically interconnecting solar roof panel assemblies 100, and/or for electrically connecting solar roof panel assemblies 100 to the electrical system of the building structure. This air gap also provides cooling to aid in keeping the solar cells operating efficiently.

In one embodiment, an air gap between solar roof panel assemblies 100 and roof deck 630 is created by first fastening battens 620 to roof deck 630, and then fastening solar roof panel assemblies 100 to battens 620. In another embodiment, a larger air gap between solar roof panel assemblies 100 and roof deck 630 is created by first fastening counter battens 610 to roof deck 630, then fastening battens 620 to counter battens 610, and then fastening solar roof panel assemblies 100 to battens 620. Battens 620 and counter battens 610 may be made of wood, plastic, metal, or any material suitable for installing on a roof deck and supporting solar roof panel assemblies 100. In some embodiments, other methods of creating an air gap between solar roof panel assemblies 100 and roof deck 630 may be used. For example, steel hat section purlins may be used as an alternative to wood battens.

After a solar roof panel assembly 100 is fastened to roof deck 630, solar roof panel assembly 100 may be electrically connected to other solar roof panel assemblies 100, to the building structure electrical system, or both. In some embodiments, the solar roof panel assemblies may be electrically interconnected only after all solar roof panel assemblies are fastened to roof deck 630. In other embodiments, the electrical interconnecting of solar roof panel assemblies may be performed “on-the-fly”, i.e., before all solar roof panel assemblies are fastened to roof deck 630.

To electrically interconnect solar roof panel assemblies 100, electrical connection elements 152 extending from electrical junction boxes 150 may be connected to electrical connection elements 152 extending from electrical junction boxes 150 of other solar roof panel assemblies 100. The solar roof panel assemblies may be electrically connected in series, in parallel, or in both series and in parallel, to create a solar panel array with a desired peak DC voltage and current. In some embodiments, additional electrical cabling 650 and/or other components may be required to perform the electrical interconnection of solar roof panel assemblies 100. Electrical connection elements 152 and any additional electrical cabling 650 may be run along the air gap between the solar roof panel assemblies and the roof deck.

The direct current electricity generated by the solar cells of solar roof panel assemblies 100 may be channeled to an inverter which converts the direct current electricity to alternating current electricity as required by most building structure electrical systems and utility grids. Depending on the location of the inverter, electrical components such as cabling required to connect the solar cells to the inverter may be passed through a hole in roof deck 630. In some embodiments, the electrical components pass through the hole into the attic space below roof deck 630. In some embodiments, only a single roof penetration is required. In other embodiments, multiple roof penetrations may be required. In some embodiments, no roof penetrations are required. Because most, or even all, electrical components may be placed in the air gap, roof penetrations may be kept to a minimum.

Solar cells perform best when placed in optimal locations on a roof. For example, south-facing solar cells may have the highest energy output, but east- and west-facing solar cells may also be acceptable. Furthermore, solar cells should be placed in direct sunlight and should not be shaded by trees, neighboring buildings, or other objects. Consequently, not every roof panel installed during new construction must be a solar roof panel assembly 100, and optimal target sites for solar roof panel assemblies 100 should be identified. In some embodiments, non-solar roof panels 640 may be installed alongside solar roof panel assemblies 100.

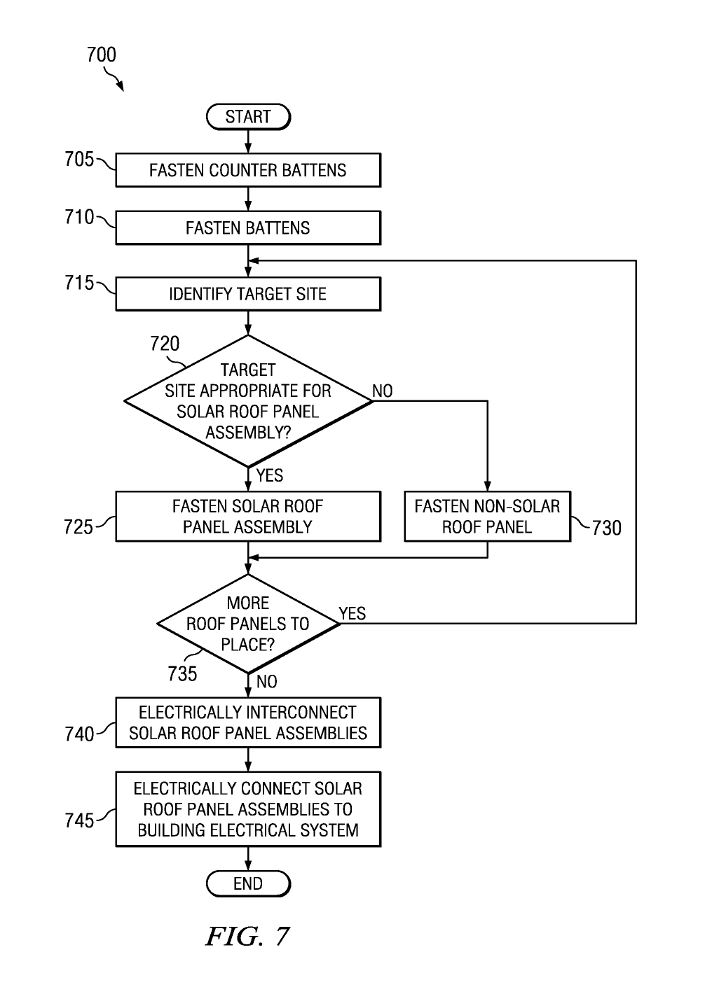

FIG. 7 is a flowchart illustrating an example method 700 for new construction installation of solar roof panel assemblies 100. Counter battens may be fastened 705 to the roof deck. Battens may be fastened 710 to the counter battens. A target site for roof panel placement may be identified 715. If, at step 720, the target site is an appropriate site for solar roof panel assembly placement, then a solar roof panel assembly may be fastened 725 to the battens. If, at step 720, the target site is not an appropriate site for solar roof panel assembly placement, then a non-solar roof panel may be fastened 730 to the battens. If, at step 735, there are more roof panels to place, then another target site for roof panel placement may be identified 715. If, at step 735, there are no more roof panels to place, then the fastened solar roof panel assemblies are electrically interconnected 740. The electrically-interconnected solar roof panel assemblies are then electrically connected 745 to the electrical system of the building structure, and the installation is complete.

Although method 700 recites specific steps for new construction installation of solar roof panel assemblies 100, other methods using additional steps, fewer steps, different steps, or a combination are contemplated. For example, as stated above, in some embodiments, the solar roof panel assemblies may be electrically interconnected only after all solar roof panel assemblies are fastened, while in other embodiments, the electrical interconnecting of solar roof panel assemblies may be performed “on-the-fly”, i.e., before all solar roof panel assemblies are fastened.

### Retrofit Installation

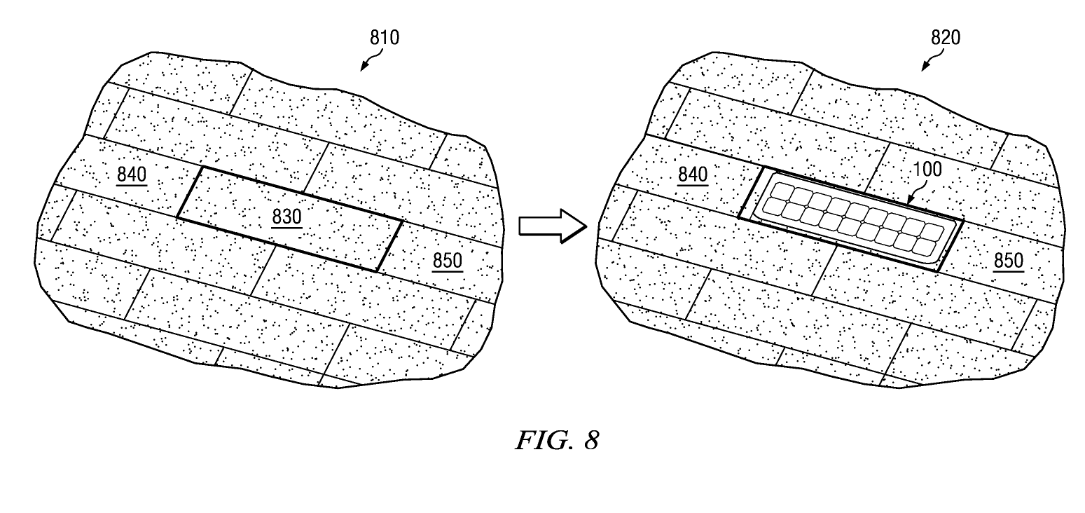

FIG. 8 illustrates an example retrofit installation of a solar roof panel assembly 100. Example roof 810 was previously installed on a building structure. One or more solar roof panel assemblies 100 may be installed on roof 810 without compromising the appearance and integrity of roof 810. Once a target site for a solar roof panel assembly is identified, any roof panels occupying the target site may be removed. In some embodiments, the roof panels occupying the target site may have been previously removed or may have become dislodged in some other manner. In the embodiment shown in FIG. 8, previously-installed roof panel 830 may be removed, leaving adjacent previously-installed roof panels 840 and 850 intact. Solar roof panel assembly 100 may then be installed in the space previously occupied by roof panel 830, resulting in retrofitted solar roof 820. Although only one solar roof panel assembly 100 is shown in this example, the installation of multiple solar roof panel assemblies 100 is contemplated to completely retrofit an existing roof. In such multiple-panel installations, the solar roof panel assemblies may be installed adjacent to one another, in groups of adjacent panels, not adjacent to one another, or a combination of groups of adjacent and non-adjacent panels. Installation procedures, including electrical connection procedures, as described above for new construction installation may also apply for retrofit installation.

In some embodiments, some or all of previously-installed roof panel 830 and adjacent previously-installed roof panels 840 and 850 may be covered with a stone coating similar in function and/or appearance to stone coating 120 of solar roof panel assembly 100. In some embodiments, some or all of previously-installed roof panel 830 and adjacent previously-installed roof panels 840 and 850 may have overlap portions and/or underlap portions similar in function and/or appearance to overlap portion 170 and underlap portion 172 of solar roof panel assembly 100. Furthermore, in some embodiments, some or all of previously-installed roof panel 830 and adjacent previously-installed roof panels 840 and 850 may have other similar coatings and configurations as described above and shown in FIGS. 1A and 1B for solar roof panel assembly 100. Such similarities in form and function between the existing roof panels and retrofitted solar panels may provide for an attractive appearance and for ease of installation. Although roof 810 shows adjacent previously-installed roof panels 840 and 850 as horizontally left and right of previously-installed roof panel 830, such adjacent roof panels may be vertically above and below previously-installed roof panel 830, or in some other contiguous arrangement.

In some embodiments, multiple previously-installed roof panels may have formerly occupied the target site for a single solar roof panel assembly 100. And in some embodiments, a single previously-installed roof panel may have formerly occupied the target site for multiple solar roof panel assemblies 100. But in other embodiments, exactly one previously-installed roof panel 830 may have formerly occupied the target site for a single solar roof panel assembly 100. In such embodiments, the previously-installed roof panel 830 may be a DECRA® Roofing Systems roof panel, and may further be a DECRA® Roofing Systems Tile panel, a DECRA® Roofing Systems Shake panel, or a DECRA® Roofing Systems Shingle Plus panel.

While various embodiments in accordance with the disclosed principles have been described above, it should be understood that they have been presented by way of example only, and are not limiting. Thus, the breadth and scope of the invention(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1-15. (canceled)

16. A method for installing a solar roof panel assembly above a roof deck of a building structure, the building structure comprising a building structure electrical system, and the solar roof panel assembly for converting light energy into electricity, the method comprising:
identifying a target site above the roof deck;
fastening the solar roof panel assembly to the roof deck at the target site such that an air gap is created between the solar roof panel assembly and the roof deck; and
electrically connecting at least one electrical connection element to the building structure electrical system, wherein the solar roof panel assembly comprises:
a metal roof panel base comprising a front surface, a back surface, a reserved area on the front surface, and a non-reserved area on the front surface;
a stone coating covering at least a portion of the non-reserved area;
at least one solar cell fastened to the metal roof panel base within the reserved area;
an electrical junction box positioned on the back surface, the electrical junction box housing electrical components connected to the at least one solar cell through an aperture in the metal roof panel base; and
the at least one electrical connection element extending from the electrical junction box.

17. The method of claim 16, wherein fastening the solar roof panel assembly to the roof deck at the target site comprises fastening the solar roof panel to at least one batten, the at least one batten fastened to the roof deck.

18. The method of claim 17, wherein the at least one batten fastened to the roof deck comprises at least one batten fastened to at least one counter batten, the at least one counter batten fastened to the roof deck.

19. The method of claim 16, further comprising:
electrically connecting the at least one electrical connection element to a second solar roof panel assembly.

20. The method of claim 19, further comprising:
electrically connecting the at least one electrical connection element to a third solar roof panel assembly.

21. The method of claim 16, wherein at least one previously-installed roof panel formerly occupied the target site.

22. The method of claim 21, further comprising removing the at least one previously-installed roof panel.

23. The method of claim 21, wherein the at least one previously-installed roof panel comprises one previously-installed roof panel.

24. The method of claim 23, wherein the one previously-installed roof panel is a DECRA® Roofing Systems roof panel.

25. The method of claim 24, wherein the DECRA® Roofing Systems roof panel is selected from the group consisting of: a DECRA® Roofing Systems Tile panel, a DECRA® Roofing Systems Shake panel, and a DECRA® Roofing Systems Shingle Plus panel.

26. The method of claim 21, wherein the at least one previously-installed roof panel comprises a previously-installed roof panel stone coating, the previously-installed roof panel stone coating similar in function and appearance to the solar roof panel assembly stone coating.

27. The method of claim 21, wherein the solar roof panel assembly further comprises an overlap portion and a complementary underlap portion, and wherein a first previously-installed roof panel adjacent to the target site comprises a first previously-installed roof panel underlap portion, the first previously-installed roof panel underlap portion substantially similar to the solar roof panel assembly underlap portion.

28. The method of claim 27, wherein a second previously-installed roof panel adjacent to the target site comprises a second previously-installed roof panel overlap portion, the second previously-installed roof panel overlap portion substantially similar to the solar roof panel assembly overlap portion.

29. The method of claim 27, wherein fastening the solar roof panel assembly to the roof deck at the target site comprises aligning the overlap portion of the solar roof panel assembly with the first previously-installed roof panel underlap portion.
